(19) United States
(12) Patent Application Publication
(10) Pub. No.: US 2019/0194059 A1
(43) Pub. Date: Jun. 27, 2019

(54) CONDUCTIVE PASTE AND SOLAR CELL

(71) Applicant: NAMICS CORPORATION, Niigata-shi, Niigata (JP)

(72) Inventor: Seiya KONNO, Niigata-shi, Niigata (JP)

(73) Assignee: NAMICS CORPORATION, Niigata-shi, Niigata (JP)

(21) Appl. No.: 16/313,039

(22) PCT Filed: Jun. 20, 2017
(86) PCT No.: PCT/JP2017/022628

§ 371 Date: Dec. 23, 2018

(30) Foreign Application Priority Data
Jun. 29, 2016 (JP) 2016-128676

(51) Int. Cl. C03C 8/18; H01L 31/0224; H01B 1/22; H01L 31/02; H01L 31/068; H01L 31/18

(52) U.S. Cl. CPC C03C 8/18; H01L 31/022425; H01L 31/1804; H01L 31/0201; H01L 31/068; H01B 1/22

(57) ABSTRACT

Provided is a conductive paste for forming a bus bar electrode having high adhesive strength on a passivation film in a crystalline silicon solar cell without having a detrimental effect on the passivation film so as to affect solar cell properties. The conductive paste is a conductive paste for forming an electrode formed on a passivation film of a solar cell, containing: (A) conductive particles, (B) an organic vehicle, and (C) glass frit containing Bi₂O₃ at 10 mol % to 30 mol % and SiO₂ at 5 mol % to 30 mol %, wherein the conductive paste contains the glass frit at 0.3 parts by weight to 2 parts by weight based on 100 parts by weight of the conductive particles.

### TECHNICAL FIELD

The present invention relates to a conductive paste used to form an electrode of a semiconductor device and the like. More particularly, the present invention relates to a conductive paste for forming an electrode of a solar cell. In addition, the present invention relates to a solar cell produced using the conductive paste for electrode formation.

### BACKGROUND ART

Crystalline solar cells and other semiconductor devices using crystalline silicon, obtained by processing single crystal silicon or polycrystalline silicon into the shape of a flat plate, for the substrate thereof typically have an electrode formed using a conductive paste for electrode formation formed on the surface of the silicon substrate. Among semiconductor devices having an electrode formed in this manner, the production output of crystalline silicon solar cells has increased in recent years. These solar cells have an impurity diffusion layer, antireflection film and light incident side electrode on one surface of a crystalline silicon substrate and have a back side electrode on the other surface. Electrical power generated by the crystalline silicon solar cell can be extracted to the outside by the light incident side electrode and the back side electrode.

Conductive paste containing conductive powder, glass frit, organic hinder, solvent and other additives has been used to form the electrodes of conventional crystalline silicon solar cells. Silver particles (silver powder) are mainly used for the conductive powder.

Bismuth-based glass for electrode formation used in silicon solar cells (including single crystal silicon solar cells and polycrystalline solar cells) is described in. Patent Document 1 as an example of the glass frit contained in conductive paste. Patent Document 1 describes that this glass exhibits favorable fire-through properties.

Patent Document 2 describes an Ag electrode paste used to form a light-receiving surface side electrode of a solar cell provided with a semiconductor substrate, the light-receiving surface side electrode arranged on one of the main surfaces that functions as the light-receiving surface of the pair of mutually opposing main surfaces of the aforementioned semiconductor substrate, and a back side electrode arranged on the other main surface.

Patent Document 3 describes a thick film conductive composition containing (a) conductive metal particles selected from (1) Al, Cu, Au, Ag, Pd and Pt, (2) Al, Cu, Au, Ag, Pd and Pt alloy, and (3) a mixture thereof, (b) glass frit in the form of Pb frit, and (c) an organic medium; wherein, components (a) and (b) are dispersed in component (c), and the mean diameter of the conductive metal particles is within the range of 0.5 μm to 10.0 μm.

### PRIOR ART DOCUMENTS

### Patent Documents

[Patent Document 1] JP 2014-7212 A

[Patent Document 2] JP 5278707 B

[Patent Document 3: JP 2006-313744 A

### SUMMARY OF THE INVENTION

Problems to be Solved by the Invention

FIG. 1 shows an example of a cross-sectional schematic diagram of an ordinary crystalline silicon solar cell. As shown in FIG. 1, in a crystalline silicon solar cell, an impurity diffusion layer 4 (such as an n-type impurity diffusion layer having an n-type impurity diffused therein) is formed on a surface on the light incident side (light incident side surface) of a crystalline silicon substrate 1 (such as a p-type crystalline silicon substrate 1). An antireflective film 2 is formed on the impurity diffusion layer 4. Moreover, an electrode pattern of light incident side electrodes 20 (front side electrodes) is printed on the antireflective film 2 using a conductive paste by a method such as screen printing. The light incident side electrodes 20 are formed by drying and firing the printed conductive paste. During this firing, the conductive paste fires through the antireflective film 2. As a result of firing through the antireflective film 2 in this manner, the light incident side electrodes 20 can be formed so as to contact the impurity diffusion layer 4. Furthermore, fire-through refers to etching an insulating film in the form of the antireflective film 2 with glass frit and the like contained in the conductive paste to generate electrical continuity between the light incident side electrodes 20 and the impurity diffusion layer 4. Light is not required to enter from the back side of the p-type crystalline silicon substrate 1 (surface on the opposite side from the light incident side surface). Consequently, back side electrodes 15 (back side full-surface electrodes 15b) are typically formed over the nearly the entire surface of the back side. A p-n junction is formed at the interface between the p-type crystalline silicon substrate 1 and the impurity diffusion layer 4. The majority of incident light that has entered the crystalline silicon solar cell enters the p-type crystalline silicon substrate 1 after having penetrated the antireflective film 2 and the impurity diffusion layer 4. During this process, light is absorbed by the p-type crystalline silicon substrate 1 resulting in the generation of electron-hole pairs. These electron-hole pairs are such that electrons are separated into the light incident side electrodes 20 and holes are separated into the back side electrodes 15 by the electric field generated by the p-n junction. The electrons and holes (carriers) are extracted to the outside by way of these electrodes as electrical current.

FIG. 2 shows an example of a schematic diagram of the light incident side surface of a typical crystalline silicon solar cell. As shown in FIG. 2, light incident side electrodes 20 are arranged on the light incident side surface of the crystalline silicon power cell in the form of bus bar electrodes (light incident side bus bar electrodes 20a) and finger electrodes 20b. In the examples shown in FIGS. 1 and 2, electrons of the electron-hole pairs generated by incident light that has entered the crystalline silicon solar cell are collected in the finger electrodes 20b and further collected in the light incident side bus bar electrodes 20a. Interconnecting metal ribbon, the periphery of which is covered with solder, is soldered to the light incident side bus bar electrodes 20a. The electric current is led outside the solar cell by this metal ribbon.

FIG. 3 shows an example of a schematic diagram of the back side of a typical crystalline silicon solar cell. As shown in FIG. 3, back side TAB electrodes 15a (also referred to as back side bus bar electrodes 15a) are arranged as the back side electrodes 15. Back side full-surface electrodes 15b are arranged over nearly the entire surface of the back side with the exception of the portion where the back side TAB electrodes 15a are arranged. In the examples shown in FIGS. 1 and 3, holes among the electron-hole pairs generated by incident light that has entered the crystalline silicon solar cell are collected in the back side electrodes 15 having aluminum as the main material thereof, and collected in the back side TAB electrodes 15a having silver as the main material thereof. Aluminum becomes a p-type impurity in the crystalline silicon. As a result of forming the back side electrodes 15 using the conductive paste having aluminum as the main material thereof as the raw material of the conductive paste, a back surface field (BSF) can be formed on the back side of the crystalline silicon solar cell when firing the conductive paste. However, aluminum is difficult to solder. Consequently, bus bar electrodes having silver for the main material thereof (back side TAB electrodes 15a) are formed in order to secure an area for soldering the interconnecting metal ribbon to the back side. Since portions are present where the back side TAB electrodes 15a and back side full-surface electrodes 15b overlap, electrical contact is maintained between the two. Interconnecting metal ribbon, the periphery of which is covered with solder, is soldered to the back side TAB electrodes 15a having silver for the main material thereof. Electrical current is led outside the solar cell by this metal ribbon.

FIG. 4 shows an example of a cross-sectional schematic diagram of a passivated emitter and rear cell (also referred to as a “PER cell”). The passivated emitter and rear cell shown in FIG. 4 has a passivation film 14 on the back side thereof. Punctate openings are arranged in the back side passivation film 14. These punctate openings enable electrical contact between the crystalline silicon substrate 1 and the back side full-surface electrodes 15b. Furthermore, impurity diffusion portions 18 (p-type impurity diffusion portions) are arranged at those portions where the crystalline silicon substrate 1 and the back side electrodes 15b make contact. The impurity diffusion portions 18 are equivalent to the hack surface field (BSF) of the typical crystalline silicon solar cell shown in FIG. 1. Since nearly the entire surface of the back side is covered by the back side passivation film 14 in the case of the passivated emitter and rear cell shown in FIG. 4, surface defect density on the back side can be reduced. Consequently, in comparison with the solar cell shown in FIG. 1, the passivated emitter and rear cell shown in FIG. 4 is able to prevent carrier recombination caused by surface defects on the back side, thereby allowing the obtaining of higher conversion efficiency.

The light incident side bar electrodes 20a and finger electrodes 20b are arranged on the light incident side surface, and the back side TAB electrodes 15a and the back side full-surface electrodes 15b are arranged in the passivated emitter and rear cell shown in FIG. 4 in the same manner as the typical crystalline silicon solar cell shown in FIG. 1.

FIG. 5 shows an example of a cross-sectional schematic diagram of a passivated emitter and rear cell in the vicinity of the light incident side bus bar electrodes 20a and back side TAB electrodes 15a. In the solar cell shown in FIG. 5, the back side passivation film 14 is arranged between the back side TAB electrodes 15a and the crystalline silicon substrate 1. If the back side TAB electrodes 15a end up firing through the back side passivation film 14, a large number of surface defects end up forming in the surface (interface) of the crystalline silicon substrate 1 at those portions where the back side TAB electrodes 15 have fired through the back side passivation film 14. As a result, carrier recombination caused by surface defects in the back side increases, thereby resulting in a decrease in performance of the solar cell. Thus, the conductive paste for forming the back side TAB electrodes 15a is required to not completely fire through the back side passivation film 14 during firing. Thus, the conductive paste for forming the back side TAB electrodes 15a is required to have low fire-through properties (reactivity) with respect to the back side passivation film 14. Namely, the conductive paste for forming the back side TAB electrodes 15a of a passivated emitter and rear cell is at least required to not have a detrimental effect on the passivation film to an extent that affects the properties of the solar cell.

Furthermore, an interconnecting metal ribbon (for making an electrical connection between solar cells) is soldered to the back side TAB electrodes 15a. Thus, the back side TAB electrodes 15a of a passivated emitter and rear cell are also required to demonstrate sufficiently high adhesive strength with respect to the back side passivation film 14.

In addition, soldering adhesive strength between the back side TAB electrodes 15a and interconnecting metal ribbon soldered to the back side TAB electrodes 15a is required to be sufficiently high in order to avoid disconnections between solar cells.

Furthermore, the conductive paste for forming the light incident side bus bar electrodes 20a may also be required to demonstrate performance similar to the performance required by conductive paste for forming the aforementioned back side TAB electrodes 15a. This is because the antireflective film 2 formed on the light incident side surface also functions as a passivation film of the light incident side surface.

The present invention is an invention conceived in order to satisfy the requirements of the back side TAB electrodes and light incident light bus bar electrodes of solar cells as previously described. Namely, an object of the present invention is to provide a conductive paste for forming a bus bar electrode having high adhesive strength on a passivation film in a crystalline silicon solar cell without having a detrimental effect on the passivation film so as to affect solar cell properties.

More specifically, an object of the present invention is to provide a conductive paste for forming a back side TAB electrode having high adhesive strength on a passivation film on the back side of a passivated emitter and rear cell without having a detrimental effect on the passivation film so as to affect solar cell properties.

In addition, an object of the present invention is to provide a conductive paste for forming a light incident side bus bar electrode having high adhesive strength on an antireflective film in a crystalline silicon solar cell without having a detrimental effect on the passivation film so as to affect solar cell properties,

In addition, an object of the present invention is to provide a crystalline silicon solar cell having a bus bar electrode having high adhesive strength on a passivation film without having a detrimental effect on the passivation film so as to affect solar cell properties.

### Means for Solving the Problems

The inventors of the present invention found that, by forming a bus bar electrode of a crystalline silicon solar cell using a conductive paste containing a prescribed glass frit, a bus bar electrode having high adhesive strength can be formed on a passivation film without having a detrimental effect on the passivation film, thereby leading to completion of the present invention. The present invention has the configurations indicated below.

The present invention consists of a conductive paste as characterized by the following Configurations 1 to 6, and a solar cell as characterized by the following Configuration 7.

(Configuration 1)

Configuration 1 of the present invention is a conductive paste for forming an electrode formed on a passivation film of a solar cell, containing:

(A) conductive particles,

(B) an organic vehicle, and

(C) glass fit containing Bi₂O₃ at 10 mol % to 30 m % and SiO₂ at 5 mol % to 30 mol %; wherein,

the conductive paste contains the glass fit at 0.3 parts by weight to 2 parts by weight based on 100 parts by weight of the conductive particles.

According to Configuration 1 of the present invention, a conductive paste can be obtained for forming a bus bar electrode having high adhesive strength on a passivation film in a crystalline silicon solar cell without having a detrimental effect on the passivation film so as to affect solar cell properties. Namely, the conductive paste of Configuration 1 of the present invention can be preferably used as a conductive paste for forming a back side TAB electrode of a passivated emitter and rear cell and a conductive paste for forming a light incident side bus bar electrode of a crystalline silicon solar cell.

(Configuration 2)

Configuration 2 of the present invention is the conductive paste of Configuration 1, wherein the mean particle diameter (D50) of the conductive particles (A) is 0.4 μm to 3.0 μm.

According to Configuration 2 of the present invention, as a result of making the mean particle diameter (D50) of the conductive particles (A) contained in the conductive paste of the present invention to be 0.4 μm. to 3.0 μm, reactivity of the conductive paste to the passivation film can be inhibited during firing of the conductive paste, thereby making it possible to increase soldering adhesive strength of a metal ribbon to the resulting electrode.

(Configuration 3)

Configuration 3 of the present invention is the conductive paste of Configuration 1 or Configuration 2, wherein the organic vehicle (B) contains at least one type of vehicle selected from ethyl cellulose, rosin ester, acryl and organic solvent.

According to Configuration 3 of the present invention, as a result of the organic vehicle (B) of the conductive paste of the present invention containing at least one type of vehicle selected from ethyl cellulose, rosin ester, acryl and organic solvent, screen printing of the conductive paste can be carried out favorably and the shape of the printed pattern can be made to have a suitable shape.

(Configuration 4)

Configuration 4 of the present invention is the conductive paste of any of Configurations 1 to 3, wherein the glass frit (C) further contains B₂O₃ at 20 mol % to 40 mol %, ZnO at 10 mol % to +mol % and Al₂O₃ at 1 mol %to 10 mol %.

According to Configuration 4 of the present invention, as a result of the glass frit (C) contained in the conductive paste of the present invention further containing prescribed components, a bus bar electrode having high adhesive strength can be formed more reliably on a passivation film during firing of the conductive paste without having a detrimental effect on the passivation film so as to affect solar cell properties.

(Configuration 5)

Configuration 5 of the present invention is the conductive paste of any of Configurations 1 to 4, further containing at least one additive selected from titanium resinate, titanium oxide, cobalt oxide, cerium oxide, silicon nitride, copper-manganese-tin, aluminosilicate, and aluminum silicate.

According to Configuration 5 of the present invention, as a result of the conductive paste of the present invention containing at least one additive selected from titanium resinate, titanium oxide, cobalt oxide, cerium oxide, silicon nitride, copper-manganese-tin, aluminosilicate, and aluminum silicate, adhesive strength of an interconnecting metal ribbon to the passivation film through the bus bar electrode can be improved. Moreover, as a result of containing silicon nitride, reactivity of the conductive paste to the passivation film during firing can be inhibited. As a result, detrimental effects on the passivation film that have an effect on solar cell properties can be prevented.

(Configuration 6)

Configuration 6 of the present invention is the conductive paste of any of Configurations 1 to 5, wherein the conductive paste is a conductive paste for back side TAB electrode formation.

The use of the conductive paste of the present invention makes it possible to form an electrode of high adhesive strength on a passivation film without having a detrimental effect on the passivation film so as to affect solar cell properties. Consequently, the conductive paste of the present invention can be preferably used to form a back side TAB electrode of a passivated emitter and rear cell.

(Configuration 7)

Configuration 7 of the present invention is a solar cell in which electrodes are formed using the conductive paste described in any of Configurations 1 to 6.

According to Configuration 7 of the present invention, a solar cell, and particularly a crystalline silicon solar cell, having a bus bar electrode having high adhesive strength formed on a passivation film can be obtained without having a detrimental effect on the passivation film so as to affect solar cell properties.

### Effects of the Invention

According to the present invention, a conductive paste can be provided for forming a bus bar electrode having high adhesive strength on a passivation film in a crystalline silicon solar cell without having a detrimental effect on the passivation film so as to affect solar cell properties.

More specifically, according to the present invention, a conductive paste can be provided for forming a back side TAB electrode having high adhesive strength on a passivation film arranged on the back side in a passivated emitter and rear cell without having a detrimental effect on the passivation film so as to affect solar cell properties.

In addition, according to the present invention, a conductive paste can be provided for forming a light incident side bus bar electrode having high adhesive strength on an antireflective film (passivation film) arranged on the light incident side surface in a crystalline silicon solar cell without having a detrimental effect on the antireflective film so as to affect solar cell properties.

In addition, according to the present invention, a crystalline silicon solar cell can be provided having bus bar electrodes having high adhesive strength on a passivation film without having a detrimental effect on the passivation film so as to affect solar cell properties.

### BRIEF DESCRIPTION OF THE DRAWINGS

FIG. 1 is an example of a cross-sectional schematic diagram of a typical crystalline silicon solar cell in the vicinity where light incident side electrodes (finger electrodes) are present.

FIG. 2 is an example of a schematic diagram of the light incident side surface of a crystalline silicon solar cell.

FIG. 3 is an example of a schematic diagram of the back side of a crystalline silicon solar cell.

FIG. 4 is an example of a cross-sectional schematic diagram of a passivated emitter and rear cell in the vicinity where light incident side electrodes (light incident side finger electrodes) are present,

FIG. 5 is an example of a cross-sectional schematic diagram of a passivated emitter and rear cell in the vicinity where light incident side bus bar electrodes and back side TAB electrodes are present.

FIG. 6 is an image of the emission intensity of the photoluminescence of a sample of a back side TAB electrode produced using a conductive paste having reactivity to a passivation film as measured by photoluminescence (PL) imaging,

FIG. 7 is an image of the emission intensity of the photoluminescence of a sample of a back side TAB electrode produced using a conductive paste not having reactivity to a passivation film as measured by photoluminescence (PL) imaging.

FIG. 8 is a scanning electron microscope (SEM) micrograph obtained by observing a cross-section of the sample shown in FIG. 6 in the vicinity of a back side TAB electrode with a scanning electron microscope.

FIG. 9 is a scanning electron microscope (SEM) micrograph obtained by observing a cross-section of the sample shown in FIG. 7 in the vicinity of a back side TAB electrode with a scanning electron microscope.

### MODE FOR CARRYING OUT THE INVENTION

In the present description, “crystalline silicon” includes single crystal silicon and polycrystalline silicon. In addition, “crystalline silicon substrate” refers to a material molded into a shape suitable for forming a device, such as for forming crystalline silicon into the shape of a flat plate, for the purpose of forming an electrical element, electronic element or other semiconductor device. Any method may be used to produce the crystalline silicon. For example, the Czochralski method may be used in the case of single crystal silicon, and the casting method may be used in the case of polycrystalline silicon. In addition, polycrystalline silicon ribbon produced by another production method such as the ribbon growth method or polycrystalline ribbon formed on a substrate of a different material such as glass can also be used for the crystalline silicon substrate. In addition, “crystalline silicon solar cell” refers to a solar cell produced using a crystalline silicon substrate.

In the present description, glass frit refers to that consisting mainly of a plurality of types of oxides such as metal oxides and which is typically used in the form of glass-like particles.

The present invention is a conductive paste for forming electrodes formed on a passivation film of a solar cell. The conductive paste of the present invention contains (A) conductive particles, (B) an organic vehicle, and (C) glass frit having Bi₂O₃ and SiO₂. The content of Bi₂O₃ in the glass frit contained in the conductive paste of the present invention is 10 mol % to 30 mol % while the content of SiO₂ is 5 mol % to 30 mol %. In addition, the conductive paste of the present invention contains 0.3 parts by weight to 2 parts by weight of the glass fit based on 100 parts by weight of the conductive particles. Use of the conductive paste of the present invention makes it possible to form a bus bar electrode having high adhesive strength on a passivation film in a crystalline silicon solar cell without having a detrimental effect on the passivation film so as to affect solar cell properties.

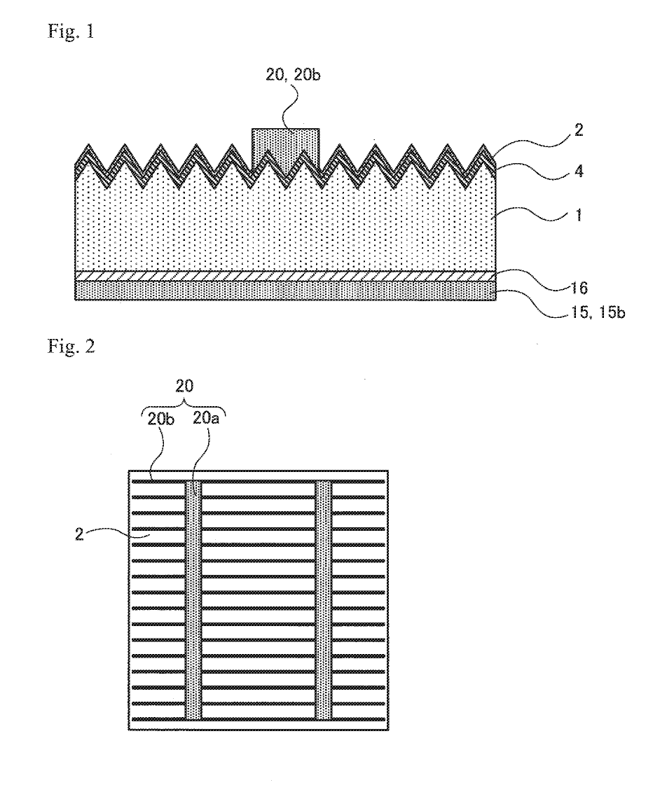

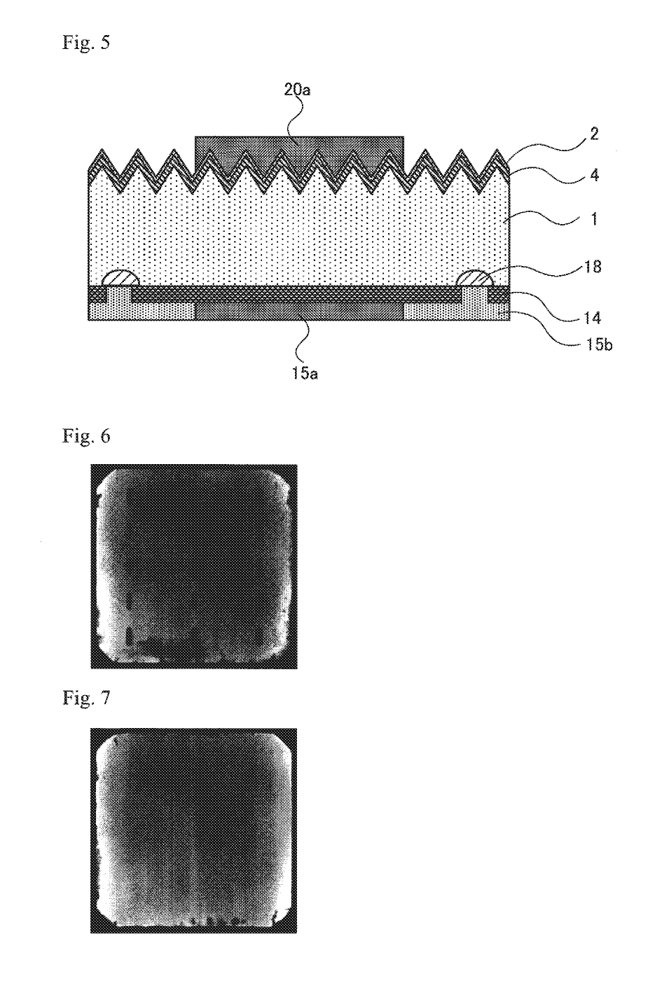

In the present description, a passivation film can be the back side passivation film 14 of a passivated emitter and rear cell as shown in FIGS. 4 and 5. Furthermore, the antireflective film 2 formed on the light incident side surface of a crystalline silicon solar cell such as the typical solar cell shown in FIG. 1 or a passivated emitter and rear cell has the function of a passivation film on the light incident side surface. Thus, in the present description, a “passivation film” refers to both the back side passivation film 14 of a passivated emitter and rear cell and the antireflective film 2 of a crystalline silicon solar cell.

The passivation film can be a film composed of a single layer or multiple layers. In the case the passivation film is composed of a single layer, it is preferably a thin film having silicon nitride (SiN) for the material thereof (SiN film) from the viewpoint of being able to effectively carry out passivation of the surface of a silicon substrate. In addition, in the case the passivation layer is composed of multiple layers, it is preferably a laminated film composed of a film having silicon nitride for the material thereof and a film having silicon oxide for the material thereof (SiN/SiO₂ film). Furthermore, in the case the passivation film is composed of a SiN/SiO₂ film, the SiN/SiO₂ film is preferably formed such that the SiO₂ film contacts the silicon substrate from the viewpoint of being able to effectively early out passivation of the surface of the silicon substrate. Furthermore, the SiO₂ film can be a natural oxide film of the silicon substrate.

Electrodes of a solar cell that can be preferably formed by the conductive paste of the present invention are bus bar electrodes formed on a passivation film of a crystalline silicon solar cell. In the present description, the bus bar electrodes include light incident side bas bar electrodes 20a formed on the light incident side surface and back side TAB electrodes (back side bus bar electrodes) 15a formed on the back side. The light incident side bus bar electrodes 20a have the function of electrically connecting finger electrodes 20b for collecting current generated by the solar cell with an interconnecting metal ribbon. Similarly, the back side TAB electrodes 15a have the function of electrically connecting back side full-surface electrodes 15b for collecting current generated by the solar cell with an interconnecting metal ribbon. Thus, the bus bar electrodes (light incident side bus bar electrodes 20a and back side TAB electrodes 15a) are not required to contact the crystalline silicon substrate 1. On the contrary, if the bus bar electrodes end up contacting the crystalline silicon substrate 1, surface defect density of the surface (interface) of the crystalline silicon substrate 1 at the portion where the bus bar electrodes make contact ends up increasing and solar cell performance ends up decreasing. Use of the conductive paste of the present invention does not have a detrimental effect on a passivation film so as to affect solar cell properties. Namely, the conductive paste of the present invention does not completely fire through to the back side passivation layer 14 due to the low fire-through properties (reactivity) with respect to the back side passivation film 14. Consequently, in the case of having formed bus bar electrodes using the conductive paste of the present invention, the passivation film at the portion that contacts the crystalline silicon substrate 1 can be maintained in its original state and increases in surface detect density caused by carrier recombination can be prevented.

Furthermore, as shown in FIGS. 1, 2 and 4, the finger electrodes 20b are arranged as light incident side electrodes 20 on the light incident side surface of a crystalline silicon solar cell. In the example shown in FIG. 2, electrons of the electron-hole pairs generated by incident light that has entered the crystalline silicon solar cell are collected in the finger electrodes 20b by way of an n-type impurity diffusion layer 4. Thus, contact resistance between the finger electrodes 20b and the n-type impurity diffusion layer 4 is required to be low. Moreover, the finger electrodes 20b are flirted by printing a prescribed conductive paste onto the antireflective film 2 having titanium nitride and the like for the material thereof and firing the conductive paste through the antireflective film 2 during firing. Thus, differing from the conductive paste of the present invention, the conductive paste for forming the finger electrodes 20b is required to have performance enabling the conductive paste to fire through the antireflective film 2.

Furthermore, in the present description, electrodes for extracting electrical current from the crystalline silicon solar cell to the outside in the form of the light incident side electrodes 20 and back side electrodes 15 may be collectively referred to as “electrodes”.

The following provides a detailed explanation of the conductive paste of the present invention.

The conductive paste of the present invention contains (A) conductive particles, (B) an organic vehicle, and (C) glass frit having Bi₂O₃ and SiO₂.

Silver particles (Ag particles) can be used for the main component of the conductive particles contained in the conductive paste of the present invention. Furthermore, the conductive paste of the present invention can also contain metals other than silver, such as gold, copper, nickel, zinc or tin, within a range that does not impair the performance of the solar cell electrodes. However, the conductive particles are preferably silver particles composed of silver from the viewpoint of obtaining low electrical resistance and high reliability. Furthermore, a large number of silver particles (Ag particles) may also be referred to as silver powder (.Ag powder). This applies similarly to other particles as well.

The particle size of the conductive particles is preferably 0.4 μm to 3.0 μm and more preferably 0.5 μm to 2.5 μm. As a result of making the particle size of the conductive particles to be within a prescribed range, reactivity of the conductive paste to the passivation film can be inhibited during firing of the conductive paste, and soldering adhesive strength of metal ribbon to the resulting electrodes can be increased. A spherical or scaly shape, for example, can be used for the shape of the conductive particles.

In general, since the size of microparticles has a certain distribution, it is not necessary for all of the particles to be have the aforementioned prescribed size, but rather particle size equivalent to 50% of the integral value of all particles (median diameter, D50) is preferably within the range of the aforementioned particle size. In the present description, median diameter (D50) is referred to as the mean particle diameter (D50). This applies similarly to the sizes of particles other than the conductive particles that are described in the present description. Furthermore, mean particle diameter (D50) can be determined by measuring particle size distribution according to the micro-tracking method (laser diffraction scattering method) and obtaining the value of mean particle diameter (D50) from the results of particle size distribution measurement. In the case of the conductive paste of the present invention, the mean particle diameter (D50) of the conductive particles is preferably 0.4 μm to 3.0 μm and more preferably 0.5 μm to 2.5 μm.

In addition, the size of the conductive particles can be expressed as BET value (BET specific surface area). The BET value of the conductive particles is preferably 0.1 m²/g to 5 m²/g and more preferably 0.2 m²/g to 2 m²/g.

Next, an explanation is provided of the glass fit contained in the conductive paste of the present invention. The glass frit contained in the conductive paste of the present invention contains Bi₂O₃ and SiO₂.

In the present description, glass fit refers to that consisting mainly of a plurality of types of oxides such as a plurality of types of Metal oxides and which is typically used in the form of glass-like particles.

The content of Bi₂O₃ in the glass frit contained in the conducive paste of the present invention is 10 mol % to 30 mol %, preferably 15 mol % to 27 mol %, and more preferably 18 mol % to 25 mol %.

The content of SiO₂ in the glass fit contained in the conductive paste of the present invention is 5 mol % to 30 mol %, preferably 10 mol % to 27 mol % and more preferably 15 mol % to 25 mol %.

As a result of making the contents of Bi₂O₃ and SiO₂ in the glass frit to be within prescribed ranges, reactivity of the conductive paste to the passivation layer during firing of the conductive paste can be inhibited during firing of the conductive paste, and adhesive strength of the resulting electrodes to the passivation film can be increased.

The conductive paste of the present invention is such that the glass frit preferably further contains B₂O₃, ZnO and Al₂O₃.

The content of B₂O₃ in the glass frit contained in the conductive paste of the present invention is preferably 20 mol % to 40 mol % and more preferably 21 mol % to 37 mol %.

The content of ZnO in the glass frit contained in the conductive paste of the present invention is preferably 10 mol % to 30 mol % and more preferably 15 mol % to 28 mol %.

The content of Al₂O₃ in the glass frit contained in the conductive paste of the present invention is preferably 1 mol % to 10 mol % and more preferably 2 mol % to 8 mol %.

As a result of making the contents of B₂O₃, ZnO and Al₂O₃ in the glass frit to be within prescribed ranges, bus bar electrodes having high adhesive strength can be more reliably formed on a passivation layer when firing the conductive paste without having a detrimental effect on the passivation layer so as to affect solar cell properties.

The glass frit of the conductive paste of the present invention can also contain other oxides such as TiO₂ in addition to the aforementioned oxides. The glass fit of the conductive paste of the present invention preferably further contains TiO₂, for example, at about 2 mol % to 8 mol %. In addition, the conductive paste of the present invention can also contain other oxide components within a range that does not impair the effects of the present invention.

The glass frit of the conductive paste of the present invention preferably contains prescribed amounts of Bi₂O₃, SiO₂, B₂O₃, ZnO and Al₂O₃. In addition, the glass frit of the conductive paste of the present invention preferably further contains a prescribed amount of TiO2 in addition to these oxides. Use of conductive paste containing glass frit composed of such components makes it possible to more reliably form bus bar electrodes having high adhesive strength on a passivation film when firing the conductive paste without having a detrimental effect on the passivation film so as to affect solar cell properties.

The conductive paste of the present invention contains 0.3 parts by weight to 2 parts by weight and preferably 0.5 parts by weight to 1.5 parts by weight of the aforementioned glass frit based on 100 parts by weight of the conductive particles. As a result of making the content of glass frit relative to the amount of conductive particles to be within a prescribed range, bus bar electrodes having high adhesive strength can be formed on a passivation layer in a crystalline silicon solar cell without having a detrimental effect on the passivation layer so as to affect solar cell properties.

There are no particular limitations on the shape of the glass frit particles and that having a spherical shape or irregular shape and the like can be used. In addition, although there are also no particular limitations on particle size, from the viewpoint of workability, the mean particle diameter (D50) of the particles is preferably within the range of 0.1 μm to 10 μm and more preferably within the range of 0.5 μm to 5 μm.

One type of particle respectively containing prescribed amounts of the required plurality of oxides can be used for the glass fit particles. In addition, particles consisting of a single oxide can be used as different particles for each of the required plurality of oxides. In addition, a plurality of types of particles having different compositions of the required plurality of oxides can also be used in combination.

In order to allow the glass frit to demonstrate proper softening performance during firing of the combustion paste of the present invention, the softening point of the glass frit is preferably 300° C. to 700° C., more preferably 400° C. to 600° C. and even more preferably 500° C. to 580° C.

The ratio of signal intensity having a peak of 529 eV to less than 531 eV to the total value of signal intensity of 526 eV to 536 eV in the oxygen binding energy of the glass frit contained in the conductive paste of the present invention when measured by X-ray photoelectron spectroscopy (XPS) is preferably 39% or less. As a result of using such glass frit, reactivity during firing of the conductive paste can be controlled so as to demonstrate the prescribed effect.

The conductive paste of the present invention contains an organic vehicle. An organic binder and solvent can be contained for the organic vehicle. The organic binder and solvent fulfill the role of adjusting the viscosity of the conductive paste and there are no particular limitations thereon. The organic binder can also be used by dissolving in the solvent.

An organic binder selected from cellulose-based resin (such as ethyl cellulose or nitrocellulose) and (meth)acrylate resin (such as polymethyl acrylate or polymethyl methacrylate) can be used for the organic binder. The organic vehicle contained in the conductive paste of the present invention preferably contains at least one type selected from ethyl cellulose, rosin ester, acryl and organic solvent. The added amount of organic binder is normally 0.2 parts by weight to 30 parts by weight and preferably 0.4 parts by weight to 5 parts by weight based on 100 parts by weight of the conductive particles.

One type or two or more types of solvents selected from alcohols (such as terpineol, α-terpineol or β-terpineol) and esters (such as hydroxyl group-containing esters, 2,2,4-trimethyl-1,3-pentanediol monoisobutyrate or butyl carbitol acetate) can be used for the solvent. The added amount of solvent is normally 0.5 parts by weight to 30 parts by weight and preferably 5 parts by weigh to 25 parts by weight based on 100 parts by weight of the conductive particles.

Moreover, additives selected from plasticizers, antifoaming agents, dispersants, leveling agents, stabilizers and adhesion promoters can be incorporated as additives in the conductive paste of the present invention as necessary. Among these, plasticizers selected from phthalic acid esters, glycolic acid esters, phosphoric acid esters, sebacic acid esters, adipic acid esters and citric acid esters can be used as plasticizers.

The conductive paste of the present invention can also contain additives other than those described above within a range that does not have a detrimental effect on the solar cell properties of the resulting solar cell. For example, the conductive paste of the present invention can further contain at least one type of additive selected from titanium resinate, titanium oxide, cobalt oxide, cerium oxide, silicon nitride, copper-manganese-tin, aluminosilicate and aluminum silicate. As a result of containing these additives, adhesive strength of an interconnecting metal ribbon to a passivation layer through bus bar electrodes can be improved. These additives can be in the form of particles (additive particles). The added amount of additive based on 100 parts by weight of the conductive particles is preferably 0.01 parts by weight to 5 parts by weight and more preferably 0.05 parts by weight to 2 parts by weight. The additive is preferably copper-manganese-tin, aluminosilicate or aluminum silicate in order to obtain higher adhesive strength.

Next, an explanation is provided of a method for producing the conductive paste of the present invention. The conductive paste of the present invention can be produced by adding conductive particles (silver particles), glass frit and other additive particles as necessary to an organic binder and solvent followed by mixing and dispersing therein.

Mixing can be carried out with, for example, a planetary mixer. In addition, dispersion can be carried out with a three roll mill. Mixing and dispersion are not limited to these methods, but rather can be carried out using various other known methods.

Next, an explanation is provided of the solar cell of the present invention. The present invention is a solar cell having electrodes formed using the aforementioned conductive paste.

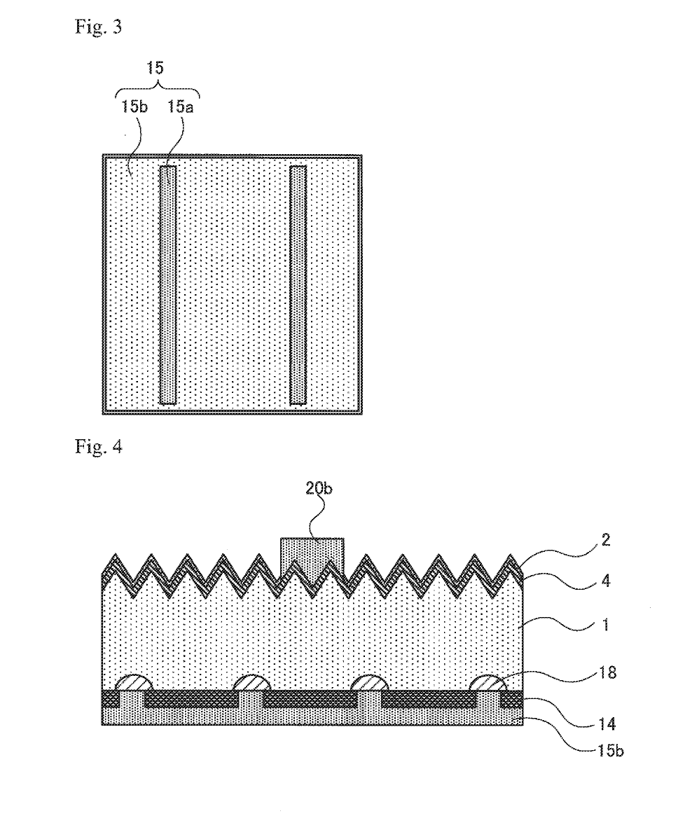

FIG. 1 shows a cross-sectional schematic diagram of a typical crystalline silicon solar cell having electrodes on both the light incident side and back side (light incident side electrodes 20 and back side electrodes 15) in the vicinity of a light incident side electrode 20. The crystalline silicon solar cell shown in FIG. 1 has light incident side electrodes 20 formed on the light incident side, an antireflective film 2, and n-type impurity diffusion layer (n-type silicon layer) 4, a p-type crystalline silicon substrate 1 and back side electrodes 15. In addition, FIG. 2 shows an example of a schematic diagram of the light incident side surface of a typical crystalline silicon solar cell. FIG. 3 shows an example of a schematic diagram of the back side of a typical crystalline silicon solar cell. In the typical crystalline silicon solar cell shown in FIG. 1, use of the conductive paste of the present invention to form light incident side bus bar electrodes 20a of the typical crystalline silicon solar cell makes it possible to obtain the light incident side bus bar electrodes 20a without having a detrimental effect on the passivation layer (antireflective film 2).

The typical crystalline silicon solar cell shown in FIG. 1 can have back side electrodes 15 employing the structure shown in FIG. 3. Namely, as shown in FIG. 3, the back side electrodes 15 typically include back side full-surface electrodes 15b containing aluminum and back side TAB electrodes 15a electrically connected to the back side full-surface electrodes 15b.

Furthermore, since the back side passivation film 14 is not present in the case of the typical crystalline silicon solar cell shown in FIG. 1, the effect of the conductive paste of the present invention of “forming electrodes so as not to have a detrimental effect on the passivation layer” cannot be demonstrated even if the rear side TAB electrodes 15a are formed using the conductive paste of the present invention. However, since use of the conductive paste of the present invention makes it possible to form the back side TAB electrodes so as to have sufficiently high soldering adhesive strength with respect to metal ribbon, even in the ease of the typical solar cell shown in FIG. 1, the conductive paste of the present invention can be used to form the back side TAB electrodes 15a.

FIGS. 4 and 5 show an example of a cross-sectional schematic diagram of a passivated emitter and rear cell. The passivated emitter and rear cell shown in FIG. 4 has the back side passivation layer 14 on the back side thereof. FIG. 5 shows an example of a cross-sectional schematic diagram of a passivated emitter and rear cell in the vicinity of the light incident side bus bar electrodes 20a and back side TAB electrodes 15a. In the passivated emitter and rear cell shown in FIG. 5, the light incident side bus bar electrodes 20a on the light incident side surface and the back side TAB electrodes 15a arranged on the back side are formed so as not to have a detrimental effect on the passivation layer (antireflective film 2 and back side passivation layer 14) as a result of using the conductive paste of the present invention.

Thus, the aforementioned conductive paste of the present invention can be preferably used as a conductive paste for forming the bus bar electrodes of a crystalline silicon solar cell. In addition, the conductive paste of the present invention can be particularly preferably used as a conductive paste for the back side TAB electrodes of a passivated emitter and rear cell.

The typical crystalline silicon solar cell shown in FIG. 1 and the passivated emitter and rear cell shown in FIG. 4 contain the light incident side bus bar electrodes 20a shown in FIG. 2 and the back side TAB electrodes 15a shown in FIG. 3. An interconnecting metal ribbon, the periphery of which is covered with solder, is soldered to the light incident side bus bar electrodes 20a and the back side TAB electrodes 15a. Electrical current generated by the solar cell is led outside the crystalline silicon solar cell by this metal ribbon. Use of the conductive paste of the present invention makes it possible to form the light incident side bus bar electrodes 20a and the back side TAB electrodes 15a having sufficiently high soldering adhesive strength with the metal ribbon.

The width of the bus bar electrodes (light incident side bus bar electrodes 20a and back side TAB electrodes 15a) can be roughly the same width as the interconnecting metal ribbon. Since the bus bar electrodes have low electrical resistance, the bus bar electrodes preferably have a wide width. On the other hand, the width of the light incident side bus bar electrodes 20a is preferably narrow in order to increase the incident area of light relative to the light incident side surface. Consequently, bus bar width is preferably 0.5 mm to 5 mm, preferably 0.8 mm to 3 mm, and more preferably 1 mm to 2 mm. In addition, the number of bus bar electrodes can be determined corresponding to the size of the crystalline silicon solar cell. More specifically, the number of bus bar electrodes can be 1, 2, 3 or 4. The optimum number of bus bar electrodes can be determined by simulating solar cell performance so as to maximize conversion efficiency of the crystalline silicon solar cell. Furthermore, since crystalline silicon solar cells are mutually connected in series by the interconnecting metal ribbon, the numbers of light incident side bus bar electrodes 20a and back side TAB electrodes 15a are preferably equal. The widths of the light incident side bus bar electrodes 20a and the back side TAB electrodes 15a are preferably equal for the same reason.

The amount of area occupied by the light incident side electrodes 20 on the light incident side surface is preferably as small as possible in order to increase the incident area of light relative to the crystalline silicon solar cell. Consequently, the width of the finger electrodes 20b on the light incident side surface is preferably as narrow as possible and the number of electrodes thereof is preferably as small as possible. On the other hand, the finger electrodes 20b are preferably wide and the number thereof is preferably large from the viewpoint of reducing electrical loss (ohmic loss). In addition, the finger electrodes 20b are preferably wide from the viewpoint of decreasing contact resistance between the finger electrodes 20b and the crystalline silicon substrate 1 (impurity diffusion layer 4). On the basis of the above, the width of the finger electrodes 20b can be 30 μm to 300 μm, preferably 50 μm to 200 μm, and more preferably 60 μm to 150 μm. In addition, the number of bus bar electrodes can be determined corresponding to the size of the crystalline silicon solar cell and the width of the bus bar electrodes. The optimum width and number of finger electrodes 20b (interval between the finger electrodes 20b) can be determined by simulating solar cell performance so as to maximize conversion efficiency of the crystalline silicon solar cell.

Next, an explanation is provided of a method for producing the crystalline silicon solar cell of the present invention.

The method for producing the solar cell of the present invention includes steps for forming bus bar electrodes by printing the aforementioned conductive paste on the impurity diffusion layer 4 of the crystalline silicon substrate 1 or on the antireflective film 2 on the impurity diffusion layer 4 followed by drying and firing. The following provides a more detailed explanation of the method for producing the solar cell of the present invention.

The method for producing the crystalline silicon solar cell of the present invention includes a step for preparing a single conductivity type (p-type or n-type) of crystalline silicon substrate 1. A p-type crystalline silicon substrate, and more specifically, a p-type single crystal silicon substrate, can be used for the crystalline silicon substrate 1.

Furthermore, the surface on the light incident side of the crystalline silicon substrate 1 preferably has a pyramid-like textured structure from the viewpoint of obtaining high conversion efficiency.

Next, the method for producing the crystalline silicon solar cell of the present invention includes a step for forming an impurity diffusion layer 4 of another conductivity type on the other surface of the crystalline silicon substrate 1 prepared in the aforementioned step. For example, in the case a p-type crystalline silicon substrate 1 is used for the crystalline silicon substrate 1, an n-type impurity diffusion layer having an n-type impurity in the form of P (phosphorous) diffused therein can be formed for the impurity diffusion layer 4. Furthermore, a crystalline silicon solar cell can also be produced using an n-type crystalline silicon substrate. In that case, a p-type impurity diffusion layer is formed for the impurity diffusion layer.

When forming the impurity diffusion layer 4, the impurity diffusion layer 4 can be formed so that the sheet resistance of the impurity diffusion layer 4 is 40 Ω/□ (ohm/square) to 150 Ω/□ and preferably 45 Ω/□ to 120 Ω/□.

In addition, in the method for producing the crystalline silicon solar cell of the present invention, the depth at which the impurity diffusion layer 4 is formed can be 0.3 μm to 1.0 μm. Furthermore, the depth of the impurity diffusion layer 4 refers to the depth from the surface to the p-n junction of the impurity diffusion layer 4. The depth of the p-n junction can be taken to be the depth from the surface of the impurity diffusion layer 4 to the location where the impurity concentration in the impurity diffusion layer 4 reaches the impurity concentration of the substrate.

Next, the method for producing the crystalline silicon solar cell of the present invention includes a step for forming the antireflective film 2 on the surface of the impurity diffusion layer 4 formed in the aforementioned step. A silicon nitride film (SiN film) can be formed for the antireflective film 2. In the case of using a silicon nitride film for the antireflective film 2, the layer containing the silicon nitride film also has the function of a front side passivation film. Consequently, in the case of using a silicon nitride film for the antireflective film 2, a high-performance crystalline silicon solar cell can be obtained. In addition, as a result of the antireflective film 2 being a silicon nitride film, an antireflection function can be demonstrated with respect to incident light. The silicon nitride film can be deposited by a method such as plasma-enhanced chemical vapor deposition (PECVD).

Furthermore, in the case of producing the passivated emitter and rear cell shown in FIG. 4, a back side passivation layer 14 such as silicon nitride layer is formed on the back side thereof. The back side passivation layer 14 has punctate openings formed by a prescribed patterning for the purpose of electrical connection between the crystalline silicon substrate 1 and the back side full-surface electrodes 15b. Punctate openings are preferably not formed at those portions where the back side TAB electrodes 15a are formed.

The method for producing the crystalline silicon solar cell of the present invention includes a step for forming the light incident side electrodes 20 by printing a conductive paste on the surface of the antireflective film 2 and firing. In addition, the method for producing the crystalline silicon solar cell of the present invention includes a step for forming the back side electrodes 15 by printing a conductive paste on the other surface (back side) of the crystalline silicon substrate 1 and firing.

More specifically, a pattern, of the light incident side electrodes 20 printed using a prescribed conductive paste is first dried at a temperature of about 100° C. to 150° C. for several minutes (such as 0.5 minutes to 5 minutes). Furthermore, the light incident side bus bar electrodes 20a of the pattern of light incident side electrodes 20 are preferably formed using the conductive paste of the present invention. This is because there is no detrimental effect on the passivation layer in the form of the antireflection film 2 in the case of forming the light incident side bus bar electrodes 20a using the conductive paste of the present invention. A known conductive paste for light incident side electrode formation can be used to form the light incident side finger electrodes 20b.

A prescribed conductive paste for forming the back side TAB electrodes 15a and a prescribed conductive paste for forming the back side full-surface electrodes 15b on the back side are printed and dried in order to form the back side electrodes 15 after having printed and dried the pattern of the light incident side electrodes 20. As previously described, the conductive paste of the present invention can be preferably used to form the back side TAB electrodes 15a of a passivated emitter and rear cell.

Subsequently, the printed and dried conductive paste is fired in air under prescribed firing conditions using a tubular furnace or other firing furnace. Firing conditions consist of firing in air at a temperature of preferably 500° C. to 1000° C., more preferably 600° C. to 1000° C., even more preferably 500° C. to 900° C. and particularly preferably 700° C. to 900° C. Firing is preferably carried out in a short period of time, and the temperature profile (temperature vs. time curve) during firing is preferably in the shape of a peak. For example, firing is carried out using the aforementioned temperatures for the peak temperature at a firing oven in-out time of 10 seconds to 60 seconds and preferably 20 seconds to 40 seconds.

During firing, the conductive pastes for forming the light incident side electrodes 20 and the back side electrodes 15 are preferably fired simultaneously so that both sets of electrodes are formed simultaneously. By printing a prescribed conductive paste on the light incident side electrodes and back side electrodes and simultaneously firing the conductive paste in this manner, firing for forming these electrodes is only required to be carried out once. Consequently, the crystalline silicon solar cell can be produced at lower cost.

The crystalline silicon solar cell of the present invention can be produced in the manner described above.

In the method for producing the crystalline silicon solar cell of the present invention, a conductive paste for forming the finger electrodes 20b preferably fires through the antireflective film 2 when firing the conductive paste printed on the light incident side surface of the crystalline silicon substrate 1 for forming the light incident side electrodes 20, and particularly when firing the conductive paste for forming the finger electrodes 20b. The finger electrodes 20b can thereby be formed so as to contact the impurity diffusion layer 4. As a result, contact resistance between the finger electrodes 20b and the impurity diffusion layer 4 can be reduced. The conductive paste for forming the light incident side electrodes 20, including the finger electrodes 20b, is known.

A solar cell module can be obtained by electrically connecting crystalline silicon solar cells of the present invention obtained in the manner described above with interconnecting metal ribbon and laminating with a glass plate, sealant and protective sheet and the like. A metal ribbon having a periphery covered with solder (such as a ribbon having copper for the material thereof) can be used for the interconnecting metal ribbon. Commercially available solder such as that composed mainly of tin, and more specifically, leaded solder containing lead and lead-free solder, can be used for the solder.

According to the crystalline silicon solar cell of the present invention, a high-performance crystalline silicon solar cell can be provided by forming prescribed bus bar electrodes using the conductive paste of the present invention.

### EXAMPLES

Although the following provides a detailed explanation of the present invention through examples thereof, the present invention is not limited to these examples.

In the examples and comparative examples, soldering adhesive strength of the interconnecting metal ribbon was evaluated using a measuring substrate that simulated a single crystal silicon solar cell and the degree of deterioration of the passivation film was evaluated by photoluminescence (PL) imaging. Performance of the conductive paste of the present invention in the examples and comparative examples was evaluated by evaluating the degree of deterioration of the passivation film.

<Materials and Formulation Ratios of Conductive Paste>

Compositions of the conductive paste used to produce the solar cells of the examples and comparative examples were as indicated below.

(A) Conductive Particles

Silver particles (100 parts by weight) were used for the conductive particles. The conductive particles used in Examples 1 to 15 and Comparative Examples 1 to 7 were of a spherical shape and those having the mean particle diameters (D50) shown in Tables 2 to 4 were used. Mean particle diameter (D50) was determined by measuring particle size distribution using the micro-track method (laser diffraction scattering method) and obtaining the median value (D50) from the results of particle size distribution measurement. This applies similarly to the mean particle diameters (D50) of other particles as well. Furthermore, although Table 2 lists the mean particle diameter (D50) of the silver particles of Example 1 as 0.5 μm to 2.5 μm, for example, this means that the measured value (median diameter, D50) of the mean particle diameter (D50) of the silver particles of Example 1 is within the range of 0.5 μm to 2.5 μm. This applies similarly to the mean particle diameter (D50) of the silver particles of other examples and comparative examples.

(B) Glass Frit

Glass frit A to G having the formulations shown in Table 1 was respectively used in the examples and comparative examples. The added amounts of glass frit present in the conductive pastes of Examples 1 to 15 and Comparative Examples 1 to 7 based on 100 parts by weight of the conductive particles were as shown in Tables 2, Tables 3 and 4. Furthermore, mean particle diameter (D50) of the glass frit was 2 μm.

(C) Organic Binder

Ethyl cellulose (1 part by weight) having an ethoxy content of 48% by weight to 49.5% by weight was used for the organic binder.

(D) Solvent

Butyl carbitol acetate (11 parts by weight) was used for the solvent.

Next, the materials having the aforementioned formulation ratios were mixed with a planetary mixer and further dispersed with a three roll mill to form a paste and prepare conductive pastes.

<Measurement of Soldering Adhesive Strength>

In one evaluation of the conductive paste of the present invention, test substrates for measuring soldering adhesive strength that simulated a solar cell were fabricated using the prepared conductive pastes followed by measurement of soldering adhesive strength. Furthermore, in the tests for measuring soldering adhesive strength, although both adhesive strength between the measuring substrate containing the passivation layer and electrode along with adhesive strength between the metal ribbon and electrode were measured, since the metal particles contained in the electrode were silver particles, adhesive strength between the metal ribbon and electrode was comparatively high. Thus, measuring soldering adhesive strength made it possible to measure adhesive strength between the measuring substrate containing the passivation layer and the electrode.

The method used to fabricate test substrates was as indicated below.

A p-type single crystal silicon substrate (substrate thickness: 200 μm) was used for the test substrate.

First, after having formed a silicon oxide layer at a thickness of 20 μm on the aforementioned substrate, the substrate was etched with a solution obtained by mixing hydrogen fluoride, pure water and ammonium fluoride to remove any damage on the substrate surface. Moreover, the substrate was subjected to heavy metal cleaning with an aqueous solution containing hydrochloric acid and hydrogen peroxide.

Furthermore, when measuring adhesive strength of the back side TAB electrodes 15a, it is not necessary to form a textured structure, n-type impurity diffusion layer, antireflective film 2 or light incident side electrodes 20 on the light incident side surface. Thus, the compositions thereof, which ought to have been formed on the light incident side surface during actual solar cell production, were not formed.

Next, the back side passivation film 14 in the form of a silicon nitride film was formed at a thickness of about 60 nm over the entire surface of the back side of the substrate by plasma CVD using silane gas and ammonia gas. More specifically, a silicon nitride film (passivation film 14) having a thickness of about 60 nm was formed by plasma CVD by glow discharge decomposition of a mixed gas consisting of a mixture of NH₃ and SiH₄ mixed at a ratio NH₃/SiH₄ of 0.5 and pressure of 1 torr (133 Pa).

The solar cell substrate obtained in this manner was used after cutting into squares measuring 15 mm×15 mm.

Printing of conductive paste for forming the back side TAB electrodes 15a was carried out by screen printing. Conductive pastes were used in the examples and comparative examples that contained glass frit and conductive particles as shown in Tables 2, 3 and 4, and patterns of the back side TAB electrodes 15a having a length of 1.3 mm and width of 2 mm were printed on the back side passivation film 14 of the aforementioned substrate so that the film thickness was about 20 μm. Subsequently, the printed patterns were dried for about one minute at 150° C.

Furthermore, the light incident side electrodes 20 are not required during measurement of the adhesive strength of the back side TAB electrodes 15a. Thus, the light incident side electrodes 20 were not formed.

The substrates having conductive pastes printed on the surface thereof in the manner described above were fired in air under prescribed firing conditions using a near infrared firing oven (NGK insulators, Ltd., Fuel Cell Rapid Firing Test Kiln) using a halogen lamp for the heat source. Firing conditions consisted of firing in air at a peak temperature of 775° C. and firing oven in-out time of 30 seconds. Substrates for measuring soldering adhesive strength were produced in the manner described above.

Samples for measuring adhesive strength of the soldered metal ribbons were fabricated and measured in the manner indicated below. An interconnecting metal ribbon in the form of copper ribbon (width: 1.5 mm ×total thickness: 0.16 mm, covered with eutectic solder (weight ratio of tin:lead=64:36) at a film thickness of about 40 μm) was soldered on the back side TAB electrodes 15a of the aforementioned square substrate for measuring soldering adhesive strength measuring 15 mm on a side using flux at a temperature of 250° C. for 3 seconds to obtain a sample for measuring adhesive strength. Subsequently, the ring-shaped portion provided on one end of the ribbon was pulled in a direction 90 degrees relative to the substrate surface with a digital force gauge (AB&D Co., Ltd., Model AD-4932-50N Digital Force Gauge) followed by measuring soldering adhesive strength by measuring adhesive fracture strength. Furthermore, 10 samples were fabricated and the measured value was determined by taking the average of the 10 samples. Furthermore, in the case adhesive strength of the metal ribbon was greater than 1 N/mm, the sample was evaluated as having satisfactory adhesive strength capable of withstanding actual use.

The results of measuring soldering adhesive strength are shown in Tables 2, 3 and 4.

<Evaluation of Reactivity of Conductive Paste to Passivation Film>

Reactivity of conductive paste to passivation film was evaluated by the photoluminescence imaging (PL) method (PL method). The PL method can be used to evaluate the reactivity of conductive paste to a passivation film in a non-destructive and non-contact manner and in a short period of time. More specifically, the PL method consists of irradiating a sample with light having energy greater than the band gap to cause the sample to emit light followed by evaluating the state of crystal defects as well as surface and interface defects based on the emission status. In the case the sample has defects and surface/interface defects in single crystal silicon, the defects act in the form of recombination center of electron-hole pairs generated as a result of being irradiated with light, resulting in a corresponding decrease in band-edge emission intensity attributable to photoluminescence. In other words, in the case the passivation film has been eroded by the printed/fired electrodes and surface defects have formed at the interface between the passivation film and single crystal silicon substrate (namely, surface of the single crystal silicon substrate), the emission intensity of photoluminescence decreases at those portions where surface defects have formed (namely, those portions where electrodes have been formed on the sample). The magnitude of this photoluminescence emission intensity can be used to evaluate reactivity of a test paste to a passivation film.

Measuring substrates for evaluating according to the PL method were fabricated in the same manner as in the case of measuring soldering adhesive strength. Namely, measuring substrates having a silicon nitride film (back side passivation film 14) formed to a film thickness of about 60 nm on the back side of a single crystal silicon substrate and cut into squares measuring 15 mm×15 mm were used for the measuring substrates.

Printing of conductive paste for forming the back side TAB electrodes 15a was carried out by screen printing. Conductive pastes were used in the examples and comparative examples that contained glass frit and conductive particles as shown in Tables 2, 3 and 4. Patterns of the back side TAB electrodes 15a having a width of 2 mm were printed on the back side passivation film 14 of the aforementioned substrate so that the film thickness was about 20 μm. Subsequently, the printed patterns were dried for about one minute at 150° C. Furthermore, the shape of the back side TAB electrodes 15a in the lengthwise direction was such that electrodes having a length of 15 mm were arranged linearly in rows of six each (punctate pattern) at intervals of 15 mm.

Furthermore, the light incident side electrodes 20 are not required during measurement of the back side TAB electrodes 15a according to the PL method. Thus, the light incident side electrodes 20 were not formed.

The substrates having an electrode pattern printed on the surface thereof with conductive paste as described above were fired in air under prescribed conditions using a near infrared firing oven (NGK Insulators, Ltd., Fuel Cell Rapid Firing Test Kiln) using a halogen lamp for the heat source. Firing conditions consisted of firing in air at a peak temperature of 775° C. and firing oven in-out time of 30 seconds. Substrates for measuring according to the PL method were produced in the manner described above.

The Photoluminescence Imaging System manufactured by BT Imaging Pty. Ltd. (Model LIS-R2) was used for PL measurement. Samples were irradiated with light from an excitation light source (wavelength: 650 nm, output: 3 mW) to obtain images of the emission intensity of photoluminescence.

FIGS. 6 and 7 indicate images of the emission intensity of photoluminescence as measured according to the PL method. A conductive paste ordinarily used to form light incident side electrodes (namely, a conductive paste capable of firing through a passivation film) was used to fabricate the sample shown in FIG. 6. As is clear from FIG. 6, images of those portions where the back side TAB electrodes 15a are formed appear dark. This indicates that the emission intensity of photoluminescence of the portions where the back side TAB electrodes 15a are formed has decreased. Thus, in the case of the sample shown in FIG. 6, as a result of having formed the back side TAB electrodes 15a, the passivation function attributable to the passivation film has been lost and surface defect density on the surface of the single crystal silicon substrate can be said to have increased. In Tables 2, 3 and 4, the term “Present” is indicated in the column entitled “Reactivity of conductive paste to passivation film” for samples in which a decrease in photoluminescence emission intensity was observed in this manner. In addition, in the case of the sample shown in FIG. 7, a decrease in the emission intensity of photoluminescence was not observed. The term “Absent” is indicated in the column entitled “Reactivity of conductive paste to passivation film” for samples in which a decrease in photoluminescence emission intensity was not observed in this manner. In the case of forming the back side TAB electrodes 15a using a conductive paste for which “Reactivity of conductive paste to passivation film” has been judged to be “Present”, the conductive paste can be said to have a detrimental effect on the passivation film so as to affect solar cell properties.

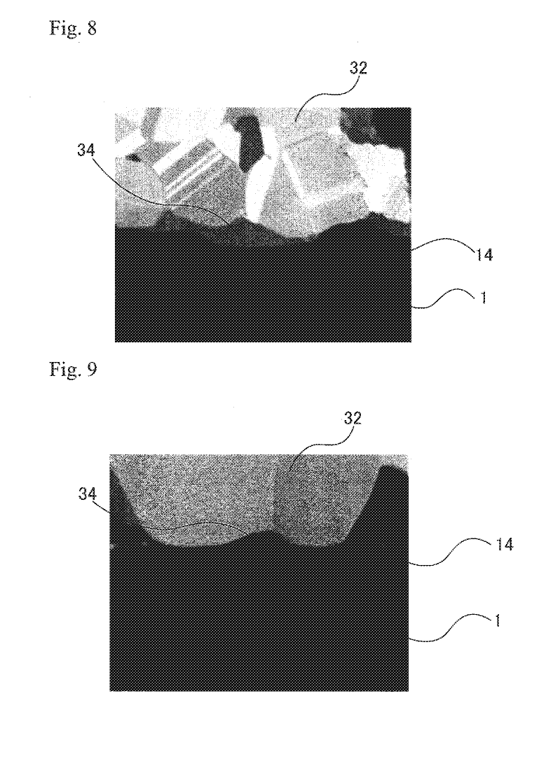

Furthermore, cross-sections of the samples shown in FIGS. 6 and 7 were observed with a scanning electron microscope (SEM) for the purpose of confirmation. FIG. 8 indicates a SEM micrograph of the back side of the sample shown in FIG. 6 having the back side TAB electrodes 15a formed thereon. In addition, FIG. 9 indicates a SEM micrograph of the back side of the sample shown in FIG. 7 having the back side electrodes 15a formed thereon. As is clear from FIG. 8, in the case of a sample for which “Reactivity of conductive paste to passivation film” has been judged to he “Present”, portions are present where the back side passivation film 14 has been eroded by glass frit 32, thereby resulting in a loss of a portion of the back side passivation film 14. On the other hand, as is clear from FIG. 9, in the case of a sample for which “Reactivity of conductive paste to passivation film” has been judged to be “Absent”, there are hardly any portions where the back side passivation film 14 has been eroded, the shape of the back side passivation film 14 is maintained nearly in its original form even after having formed the back side TAB electrodes 15a, and the back side passivation film 14 is not eroded by the glass frit 32. On the basis of the above, it is clear that the presence or absence of reactivity of a conductive paste to a passivation film can be evaluated by measuring according to the PL method as described above.

### Examples 1 to 15 and Comparative Examples 1 to 7

Substrates for measuring soldering adhesive strength and measuring according to the photoluminescence method (PL method) of Examples 1 to 15 and Comparative Examples 1 to 7 were produced using conductive pastes obtained by adding glass frit A to G formulated as shown in Table 1 in the added amounts shown in Tables 2, 3 and 4 to fabricate substrates for measuring soldering adhesive strength and measuring according to the PL method in accordance with the methods described above. Furthermore, the additives shown in Tables 2, 3 and 4 were further added to the conductive pastes used in Examples 9 to 15. The results of measuring soldering adhesive strength and measuring according to the PL method are shown in Tables 2, 3 and 4.

As is clear from the measurement results shown in Tables 2, 3 and 4, the soldering adhesive strength (N/mm) of Examples 1 to 15 of the present invention all exhibited values of 1 N/mm or more and can be therefore be said to demonstrate favorable adhesive strength in terms of soldering adhesive strength. Namely, in the case of Examples 1 to 15, adhesive strength between the electrodes formed and the passivation film can be said to be favorable.

In addition, “Reactivity of conductive paste to passivation film” of Examples 1 to 15 of the present invention was judged to be “Absent” in all of these examples. Thus, in the ease of having formed the back side TAB electrodes 15a using the conductive pastes of Examples 1 to 15 of the present invention, there can be said to be no detrimental effect on the passivation film so as to affect solar cell properties.

In contrast, among Comparative Examples 1 to 7, soldering adhesive strength (N/mm) of the metal ribbon of Comparative Examples 1, 4 and 7 was less than 1 N/mm. Thus, soldering adhesive strength (N/mm) of the metal ribbon of Comparative Examples 1, 4 and 7 cannot be said to be favorable in terms of soldering adhesive strength. Namely, in the case of Comparative Examples 1, 4 and 7, adhesive strength between the electrodes formed and the passivation layer cannot be said to be favorable.

In addition, the “Reactivity of conductive paste to passivation film” of Comparative Examples 2, 3, 5 and 6 was judged to be “Present” in all of these comparative examples. Thus, in the case of having formed the back side TAB electrodes 15a using the conductive pastes of Comparative Examples 2, 3, 5 and 6, there can be said to be a detrimental effect on the passivation film so as to affect solar cell properties.

On the basis of the above, in the case of Examples 1 to 15 of the present invention, it is clear that favorable results were able to be obtained for both adhesive strength between the electrodes and passivation film and reactivity of the conductive paste to the passivation film in comparison with Comparative Examples 1 to 7.

TABLE 1

| Type of glass frit | A | B | C | D | E | F | G |
|---|---|---|---|---|---|---|---|
| B₂O₃ (mol %) | 21.5 | 37.0 | 29.0 | 30.4 | 7.6 | 26.2 | 14.7 |
| ZnO (mol %) | 27.0 | 16.0 | 33.8 | 19.5 | 38.5 | 33.6 | 26.9 |
| Bi₂O₃ (mol %) | 19.0 | 25.0 | 30.4 | 9.1 | 33.6 | 27.0 | 18.8 |
| TiO₂ (mol %) | 4.5 | — | — | 3.3 | 6.5 | 5.7 | 4.6 |
| Al₂O₃ (mol %) | 3.5 | 6.5 | 6.0 | 2.6 | 5.1 | 4.5 | 3.6 |
| SiO₂ (mol %) | 24.5 | 15.5 | 0.8 | 35.1 | 8.7 | 3.0 | 31.4 |
| Total (mol %) | 100.0 | 100.0 | 100.0 | 100.0 | 100.0 | 100.0 | 100.0 |

TABLE 2

| | Comparative | | | | | | Comparative |
|---|---|---|---|---|---|---|---|
| | Example 1 | Example 1 | Example 2 | Example 3 | Example 4 | Example 5 | Example 2 |
| Mean particle diameter (D50) | 0.5~2.5 | 0.5~2.5 | 0.5~2.5 | 0.5~2.5 | 0.5~2.5 | 0.5~2.5 | 0.5~2.5 |
| of silver particles (μm) | | | | | | | |
| Type of glass frit | A | A | A | A | A | A | A |
| Added amount of glass frit | 0.2 | 0.3 | 0.5 | 0.8 | 1.5 | 2 | 2.2 |
| (parts by weight based on 100 | | | | | | | |
| parts by weight of silver | | | | | | | |
| particles) | | | | | | | |
| Soldering adhesive strength | 0.8 | 1.2 | 1.9 | 2.44 | 1.6 | 1.3 | 1.2 |
| (N/mm) | | | | | | | |
| Reactivity of conductive paste | Absent | Absent | Absent | Absent | Absent | Absent | Present |
| to passivation film | | | | | | | |

TABLE 3

| | | Comparative | Comparative | Comparative | Comparative | Comparative | | |
|---|---|---|---|---|---|---|---|---|
| | Example 6 | Example 3 | Example 4 | Example 5 | Example 6 | Example 7 | Example 7 | Example 8 |
| Mean particle diameter (D50) | 0.5~2.5 | 0.5~2.5 | 0.5~2.5 | 0.5~2.5 | 0.5~2.5 | 0.5~2.5 | 0.4 | 3 |
| of silver particles (μm) | | | | | | | | |
| Type of of glass frit | B | C | D | E | F | G | A | A |
| Added amount of glass frit | 0.8 | 0.8 | 0.8 | 0.8 | 0.8 | 0.8 | 0.8 | 0.8 |
| (parts by weight based on 100 | | | | | | | | |
| parts by weight of silver | | | | | | | | |
| particles) | | | | | | | | |
| Soldering adhesive strength | 2.1 | 2.6 | 0.9 | 1.5 | 1.4 | 0.7 | 2.02 | 1.27 |
| (N/mm) | | | | | | | | |
| Reactivity of conductive paste | Absent | Present | Absent | Present | Present | Absent | Absent | Absent |
| to passivation film | | | | | | | | |

TABLE 4

| | | Example | Example | Example | Example | Example | Example |
|---|---|---|---|---|---|---|---|
| | Example 9 | 10 | 11 | 12 | 13 | 14 | 15 |
| Mean particle diameter (D50) | 0.5~2.5 | 0.5~2.5 | 0.5~2.6 | 0.5~2.7 | 0.5~2.8 | 0.5~2.9 | 0.5~2.10 |
| of silver particles (μm) | | | | | | | |
| Type of glass frit | A | A | A | A | A | A | A |
| Added amount of glass frit | 0.8 | 0.8 | 1.8 | 2.8 | 3.8 | 4.8 | 5.8 |
| (parts by weight based on 100 | | | | | | | |
| parts by weight of silver | | | | | | | |
| particles) | | | | | | | |
| Type of additive | Titanium | Titanium | Cobalt | Cerium | Silicon | Copper- | Alumino- |
| | resinate | oxide | oxide | oxide | nitride | manganesetin | silicate and |
| | | | | | | | aluminum |
| | | | | | | | silicate |
| Added amount of additive | 1 | 0.2 | 0.2 | 0.2 | 0.1 | 1 | 1 |
| (parts by weight based on 100 | | | | | | | |
| parts by weight of silver | | | | | | | |
| particles) | | | | | | | |
| Soldering adhesive strength | 2.72 | 2.6 | 2.55 | 2.5 | 2.52 | 3.8 | 3.2 |
| (N/mm) | | | | | | | |
| Reactivity of conductive paste | Absent | Absent | Absent | Absent | Absent | Absent | Absent |
| to passivation film | | | | | | | |

1 Crystalline silicon substrate (p-type single crystal silicon substrate)

2 Antireflective film

4 Impurity diffusion layer (n-type impurity diffusion layer)

14 Back side passivation film

15 Back side electrode

15a Back side TAB electrode (back side bus bar electrode)

15b Back side electrode (back side full-surface electrode)

16 Impurity diffusion layer (p-type impurity diffusion layer)

18 Impurity diffusion portion (p-type impurity diffusion portion)

20 Light incident side electrode (front side electrode)

20a Light incident side bus bar electrode

20b Light incident side finger electrode

32 Silver

34 Glass frit

1. A conductive paste for forming an electrode formed on a passivation film of a solar cell, the conductive paste comprising:
(A) conductive particles,
(B) an organic vehicle, and
(C) a glass frit containing Bi₂O₃ at 10 mol % to 30 mol %, and SiO₂ at 5 mol % to 30 mol %, wherein the conductive paste contains the glass frit at 0.3 parts by weight to 2 parts by weight based on 100 parts by weight of the conductive particles.

2. The conductive paste according to claim 1, wherein a mean particle diameter (D50) of the conductive particles (A) is 0.4 μm to 3.0 μm.

3. The conductive paste according to claim 1, wherein the organic vehicle (B) contains at least one type of vehicle selected from ethyl cellulose, rosin ester, acryl and organic solvent.

4. The conductive paste according to claim 1, wherein the glass frit (C) further contains B₂O₃ at 20 mol % to 40 mol %, ZnO at 10 mol % to 30 mol %, and Al₂O₃ at 1 mol % to 10 mol %.

5. The conductive paste according to claim 1, further comprising at least one additive selected from titanium resinate, titanium oxide, cobalt oxide, cerium oxide, silicon nitride, copper-manganese-tin, aluminosilicate, and aluminum silicate.

6. The conductive paste according to claim 1, wherein the conductive paste is a conductive paste for back side TAB electrode formation.

7. A solar cell in which electrodes are formed using the conductive paste described in claim 1.

8. The conductive paste according to claim 2, wherein the organic vehicle (B) contains at least one type of vehicle selected from ethyl cellulose, rosin ester, acryl and organic solvent.

9. The conductive paste according to claim 2, wherein the glass frit (C) further contains B₂O₃ at 20 mol % to 40 mol %, ZnO at 10 mol % to 30 mol %, and Al₂O₃ at 1 mol % to 10 mol %.

10. The conductive paste according to claim 2, further comprising at least one additive selected from titanium resinate, titanium oxide, cobalt oxide, cerium oxide, silicon nitride, copper-manganese-tin, aluminosilicate, and aluminum silicate.

11. The conductive paste according to claim 2, wherein the conductive paste is a conductive paste for back side TAB electrode formation.

12. A solar cell in which electrodes are formed using the conductive paste described in claim 2.

13. A solar cell in which electrodes are formed using the conductive paste described in claim 3.

14. A solar cell in which electrodes are formed using the conductive paste described in claim 4.

15. A solar cell in which electrodes are formed using the conductive paste described in claim 5.

16. A solar cell in which electrodes are formed using the conductive paste described in claim 6.

17. A solar cell in which electrodes are formed using the conductive paste described in claim 8.

18. A solar cell in which electrodes are formed using the conductive paste described in claim 9.

19. A solar cell in which electrodes are formed using the conductive paste described in claim 10.

20. A solar cell in which electrodes are formed using the conductive paste described in claim 11.
